(19) United States
(12) Patent Application Publication
(10) Pub. No.: US 2007/0096793 A1
(43) Pub. Date: May 3, 2007

(54) SEMICONDUCTOR DEVICE

(75) Inventors: Katsuhiro Kato, Tokyo (JP); Kenji Ichikawa, Tokyo (JP); Atsushi Nagayama, Tokyo (JP)

Correspondence Address: GLOBAL IP COUNSELORS, LLP, 1233 20TH STREET, NW, SUITE 700, WASHINGTON, DC, 20036-2680, US

(73) Assignee: Oki Electric Industry Co., Ltd., Tokyo (JP)

(21) Appl. No.: 11/469,907

(22) Filed: Sep. 5, 2006

(30) Foreign Application Priority Data
Sep. 13, 2005 (JP) 2005-265096

(51) Int. Cl. H03H 11/40

(52) U.S. Cl. 327/524

(57) ABSTRACT

A semiconductor device includes first and second lines, a first transistor configured to electrically connect with the second line, and a second transistor configured to electrically connect the first line and the first transistor, the second transistor being turned ON when a bias voltage for operation is impressed between the first and second lines.

### BACKGROUND OF THE INVENTION

1. Field of the Invention

The present invention relates to a semiconductor device which in particular has a CMOS (complementary metal oxide semiconductor) circuit and handles with electrostatic discharge (ESD).

2. Background Information

In recent years, flat panel display devices (hereinafter referred to as FPD devices), as typified by liquid crystal display panels, have come to be widely used. Usually, an FPD device has a control semiconductor integrated circuit (hereinafter referred to as a control semiconductor device) for switching certain pixels on and off in accordance with image information.

The image quality of a display device such as an FPD device is mainly determined by the gradient and contrast ratio that the display device possesses. The gradient is one factor that determines fineness of an image, and the contrast ratio is one factor that determines the sharpness of an image. Generally, the larger the gradient, i.e., the larger the number of gradation sequences, the finer the image becomes. Moreover, the larger the contrast ratio, i.e., the greater the light difference and color difference between gradation sequences, the sharper the image becomes. Accordingly, by securing a sufficient contrast ratio and increasing the gradient, it will become possible to obtain a high quality image.

However, when the gradient is increased, the contrast ratio between gradation sequences will become smaller. Therefore, in order to both secure a sufficient contrast ratio and increase the gradient, it is necessary to secure a sufficient potential difference between gradation sequences by raising the supply voltage to the control semiconductor device. Conventionally, in order to secure the necessary contrast ratio and gradient, a comparatively high voltage, generally in a range of about more than several to several dozen volts (V), is supplied to the control semiconductor device.

The control semiconductor device used in a conventional FDP device is typically a semiconductor device having a MOS structure (hereinafter referred to as a MOS structured device).

A typical MOS structured device has a structure in which a gate electrode is formed on a thin insulation film formed on a shallow doped region, by which a highly integrated structure is made possible. However, because of such structure, the MOS structured device has a structural flaw in that it might be easily damaged by ESD entering from the outside. In other words, because of the MOS structure, the control semiconductor device set in the display device can only have a poor robustness to ESD from the outside. This is not only a problem with a semiconductor device which is set in a display device such as an FDP device and which operates under comparatively high voltage in a range of about more than several to several dozen volts (such semiconductor device will be referred to as a high voltage semiconductor device), but is also a problem with a semiconductor device operating under normal voltage in a range of about 3 to 5 volts (such semiconductor device will be referred to as a low voltage semiconductor device).

Conventionally, in order for the MOS structured device to gain improved robustness against ESD, an nMOS with a grounded gate (i.e., a grounded gate nMOS, hereinafter referred to as a GGNMOS) is disposed between a power supply line VDD and a grounding line GND to function as a protective circuit (also called a protective element). Laid-Open Japanese Patent Application No. 2002-268614 (hereinafter referred to as patent reference 1) shows an example of such structure.

FIG. 1 shows the circuit structure of a semiconductor device 900 having a GGNMOS 910 as a protective circuit.

As shown in FIG. 1, the semiconductor device 900 has a structure in which a GGNMOS 910 functioning as a protective circuit, an internal circuit 920, and a parasitic diode 930 that is parasitic in the internal circuit 920, are connected in parallel in between a power supply line VDD and a grounding line GND.

FIG. 2 is a sectional view of a layer structure of the GGNMOS 910 formed on a p type semiconductor substrate (hereinafter referred to as a p type substrate), for instance. As shown in FIG. 2, the GGNMOS 910 has a p type substrate 1, a gate insulation film 2, a gate electrode 3, a drain 4, a source 5, and a back gate 6. The drain 4 and the source 5 are diffusion regions with n type conductivity which are formed by having certain regions of the p type substrate 1 doped with n type impurities. The drain 4 is connected to a power supply line VDD, and the source 5 is connected to a grounding line GND. The gate electrode 3 is formed on a thin layer of gate insulation film 2 which is formed on a region overlaid between the drain 4 and the source 5. The gate electrode 3 is also connected to the grounding line GND. The back gate 6 is an electrode for controlling the potential of the p type substrate 1, and it is a diffusion region with p type conductivity formed by doping a certain region of the p type substrate 1 with p type impurities.

Against positive surge current, the GGNMOS 910 operates while having a bipolar transistor, in which the collector is connected to the drain 4, the emitter is connected to the source 5, and the base is connected to the back gate 6 via a substrate resistance R1 of the p type substrate 1, and is parasitic therein (hereinafter, such bipolar transistor will be referred to as a parasitic bipolar transistor). Therefore, when positive surge current is inputted to the power supply line VDD, for instance, the drain voltage of the parasitic bipolar transistor parasitic in the GGMOS 910 will rise, after which the parasitic bipolar transistor will turn on. By this operation, the surge current can be dissipated to the grounding line GND via the parasitic bipolar transistor, and thereby, the internal circuit 920 can be prevented from being damaged.

On the other hand, against the negative surge current, the GGNMOS 910 operates while having a PN junction diode, in which the p type substrate 1 is applied as an anode and the n type drain 4 is applied as a cathode, being parasitic therein. Therefore, when negative surge current is inputted to the power supply line VDD, for instance, a drain voltage applied between the p type substrate 1 functioning as the anode and the drain 4 functioning as the cathode will immediately reach a forward voltage Vf of the PN junction, by which the surge current will be immediately dissipated to the grounding line GND via the PN junction diode. By this operation, the internal circuit 920 can be prevented from being damaged. The forward voltage Vf of the PN junction may be about 0.6V when the p type substrate 1 is a silicon substrate, for instance.

In the meantime, with respect to a conventional semiconductor device, preventing possible damage which could be caused by noise is also a problem to face in addition to obtaining sufficient robustness against ESD. Preventing possible damage which could be caused by noise is extremely difficult, particularly with respect to a high voltage semiconductor device operating under comparatively high voltage such as the control semiconductor device described above, as compared to a low voltage semiconductor device operating under comparatively low voltage. A reason for such problem will be explained below.

FIG. 3 shows the approximate relationship between a drain voltage V_{D} and a drain current I_{D} (hereinafter, such relationship will be referred to as the ‘I-V characteristic’) of a GGNMOS (i.e., a high voltage GGNMOS) manufactured through a process for a high voltage semiconductor device (hereinafter referred to as a high withstand voltage process) and the I-V characteristic of a GGNMOS (i.e., a low voltage GGNMOS) manufactured through a process for a low voltage semiconductor device (hereinafter referred to as a low withstand voltage process) at the time when a surge current is input to the high GGNMOS and the low GGNMOS.

In FIG. 3, the line A-A represents the slope of a characteristic curve after a parasitic bipolar transistor of the high voltage GGNMOS is turned on by a positive surge current and the line B-B represents the slope of a characteristic curve after a parasitic bipolar transistor of the low voltage GGNMOS is turned on by a positive surge current. Point f indicates the intersection of the line A-A and the operating voltage of high voltage semiconductor device. Point f shows that a great amount of current flows through the parasitic bipolar transistor when the GGNMOS has been supplied with operating voltage, and the parasitic bipolar transistor turns on by noise at that time. Therefore, at the point f, the parasitic bipolar transistor receives damage. In contrast, point g indicates the intersection of the line B-B and the operating voltage of low voltage semiconductor device. Point g shows that a small amount of current flows through the parasitic bipolar transistor when the GGNMOS has been supplied operating voltage, and the parasitic bipolar transistor turns on by noise at that time. Therefore, at the point g, the parasitic bipolar transistor dose not receive damage.

As shown in FIG. 3, the slope of the characteristic curve after the parasitic bipolar transistor of the high voltage GGNNMOS is turned on by a positive surge current (i.e., line A-A′) and the slope of the characteristic curve after the parasitic bipolar transistor of the low voltage GGNMOS is turned on by a positive surge current (i.e., line B-B′) are approximately the same. Each of these slopes indicates the ease with which the surge current flows with respect to each of the parasitic bipolar transistors (i.e., the ON-resistance after the parasitic bipolar transistor is turned on). This means that the ON-resistance after each parasitic bipolar transistor is turned on determines the surge current capability of the protective circuit. Each of the parasitic bipolar transistors can let the surge current flow more quickly from power supply line VDD to the grounding line GND as the slope of the characteristic curve gets steeper. As a result, the surge current can be effectively drawn into the protective circuit itself without letting the surge current flow into an internal circuit which is an object of protection, and thus, the semiconductor device will be able to improve its robustness against ESD.

Normally, the ON-resistance of the parasitic bipolar transistor is set to a comparatively low value in a range of about a few to more than several ohms (Ω), regardless of whether a high voltage process or a low voltage process is applied. An ON-resistance set to a comparatively low value may be a factor in the deterioration of the breakdown resistance characteristic of the high voltage semiconductor device against noise at the time of actual operation. One reason for such problem will be explained below.

In the case of the low voltage semiconductor device, normally, a bias voltage to be applied between the power supply line VDD and the grounding line GND at the time of actual operation is in a range of about 3.3V to 5.5V. On the other hand, in the case of the high voltage semiconductor device, a bias voltage to be applied between the power supply line VDD and the grounding line GND at the time of actual operation is in a range of about several to several dozen volts. Therefore, the bias voltage to be applied to the high voltage semiconductor device will be about ten times the bias voltage to be applied to the low voltage semiconductor device.

Here, for instance, by setting the operation voltage of the high voltage semiconductor device to 40V, and the ON-resistance of the parasitic bipolar transistors parasitic in the GGNMOSs of the low voltage semiconductor device and the high voltage semiconductor device, respectively, to 10 Ω, the current that will flow into the parasitic bipolar transistor of the low voltage semiconductor device when noise is generated will be in a range of about 0.33 A (ampere) to 0.55 A, while the current to flow into the parasitic bipolar transistor of the high voltage semiconductor device when noise is generated will be 4 A. This means that when noise is generated, the current flowing into the parasitic bipolar transistor of the high voltage semiconductor device will be ten times greater than the current flowing into the parasitic bipolar transistor of the low voltage semiconductor device.

Normally, with respect to a MOS structured device, it is considered unlikely that the device will be damaged when a current of about a few milliamperes (mA) flows instantly into the device, although it is highly possible that the device will be damaged instantly when a current of one ampere or more flows into the device. Therefore, with respect to a conventional high voltage semiconductor device including a protective circuit to which a bias voltage in a range of several to several dozen volts is applied, there is a possibility that the device will have a permanent breakdown (e.g. wiring fusing, PN junction breakdown, etc.) generated inside the chip due to generated noise.

In the above, the possibility of noise caused breakdown has been explained in terms of the magnitude of current. However, noise caused breakdown can also be induced by an increase in heating (voltage×current) at the time when noise is generated. In this description, in order to avoid redundant explanations, the relationship between heating and the possibility of noise caused breakdown will be omitted.

In this way, with respect to the conventional high voltage semiconductor device, there is a problem in that the possibility of noise caused breakdown will become higher as one attempts to improve the robustness against ESD.

In view of the above, it will be apparent to those skilled in the art from this disclosure that there exists a need for an improved semiconductor device. This invention addresses this need in the art as well as other needs, which will become apparent to those skilled in the art from this disclosure.

### SUMMARY OF THE INVENTION

It is therefore an object of the present invention to resolve the above-described problems and to provide a semiconductor device which is capable of achieving an improved immunity against noise and an improved robustness against ESD at the same time.

In accordance with one aspect of the present invention, a semiconductor device comprises first and second power source lines, a first transistor configured to electrically connect with the second power source line, and a second transistor configured to electrically connect the first power source line, the second transistor being turned ON when a bias voltage for operation is impressed between the first and second power source lines. However, both of first and second transistors are not permitted to turn on simultaneously in actual operation. Only the first transistor is allowed to turn on every time when the bias voltage is applied to the VDD and GND. The second transistor should be kept off in normal operation except the event that the surge current is injected or the event that case the noise occurs.

These and other objects, features, aspects, and advantages of the present invention will become apparent to those skilled in the art from the following detailed description, which, taken in conjunction with the annexed drawings, discloses preferred embodiments of the present invention.

### BRIEF DESCRIPTION OF THE DRAWINGS

Referring now to the attached drawings which form a part of this original disclosure:

FIG. 1 is a circuit diagram showing an outline structure of a semiconductor device having a GGNMOS 910 as a protective circuit;

FIG. 2 is a sectional view of a layer structure of the GGMNOS 910 formed on a p type semiconductor substrate;

FIG. 3 is a schematic figure of the overall relationship between the I-V characteristic of a high GGNMOS and the I-V characteristic of a low GGNMOS when a surge current is inputted to each of the high GGNMOS and the low GGNMOS;

FIG. 4 is a circuit diagram showing an outline structure of a semiconductor device according to a first embodiment of the present invention;

FIG. 5A is a sectional view of a layer structure of a pMOS 111 and nMOS 112 in a protective circuit 110 of the semiconductor device according to the first embodiment of the present invention;

FIG. 5B is shows the I-V characteristic of the protective circuit 110 when a positive surge current is inputted to the VDD of the semiconductor device according to the first embodiment of the present invention;

FIG. 6A is a sectional view of a layer structure of a pMOS 111 and nMOS 112 in a protective circuit 110 of the semiconductor device according to the first embodiment of the present invention;

FIG. 6B is shows the I-V characteristic of the protective circuit 110 when a negative surge current is inputted to the VDD of the semiconductor device according to the first embodiment of the present invention;

FIG. 7 is a circuit diagram showing an outline structure of a semiconductor device of a comparative example 1;

FIG. 8 is a circuit diagram showing an outline structure of a semiconductor device according to a second embodiment of the present invention;

FIG. 9 is a circuit diagram showing an outline structure of a semiconductor device according to a third embodiment of the present invention; and

FIG. 10 is a circuit diagram showing an outline structure of a semiconductor device according to a fourth embodiment of the present invention.

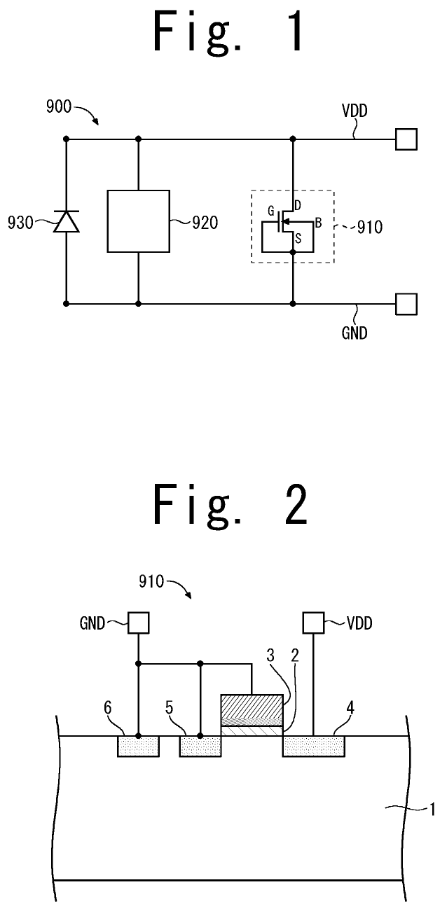

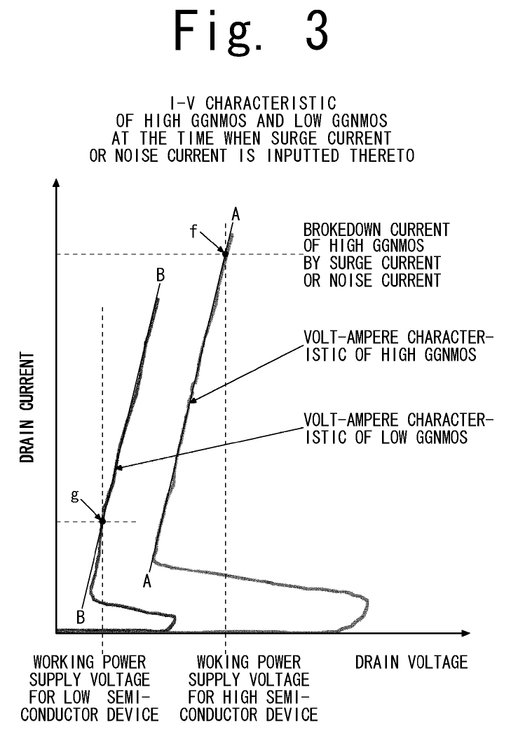

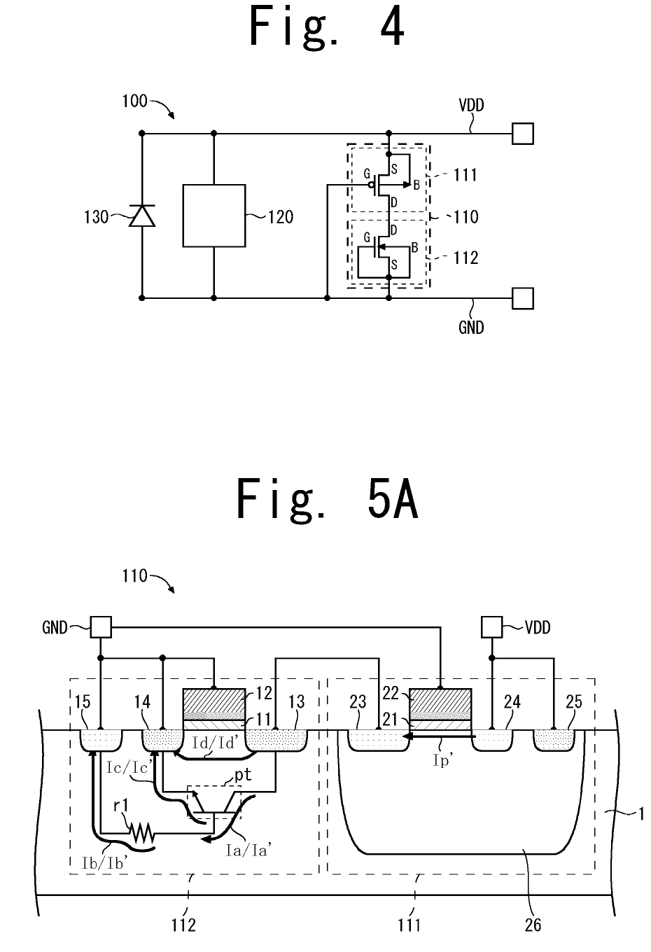

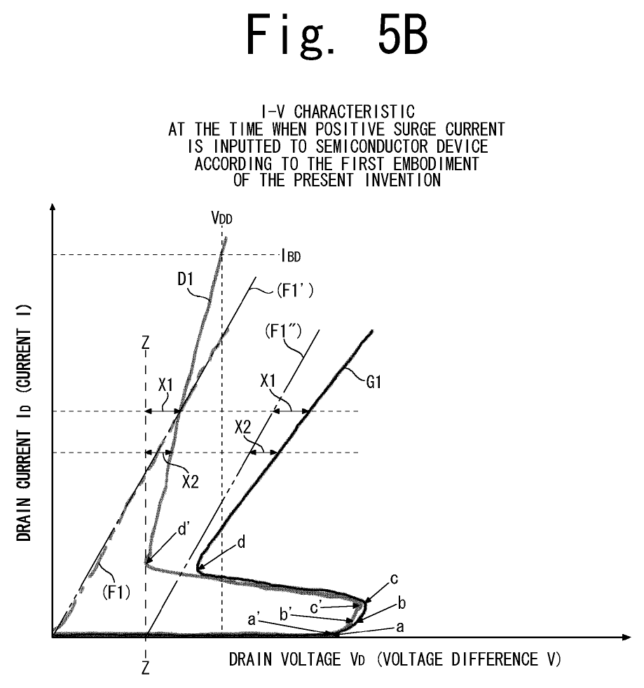

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

First Embodiment

First, a first embodiment of the present invention will be described in detail with reference to the drawings. The structure shown in each drawing is shown in certain shape, size and position in a way simple enough to show the outline of the present invention. Therefore, the present invention is not limited to the shape, size and position that are shown in the drawings. Moreover, numerical values indicated in the following description are only given as examples, and therefore, they are not in the nature of limiting the present invention. These conditions apply to all the embodiments.

In this embodiment, a semiconductor device manufactured through a high withstand voltage process and which operates by means of a comparatively high operation voltage in a range of about several to several dozen volts will be described as an example. However, the present invention is not limited by such factors, and may be a semiconductor device which operates by means of a normal operation voltage in a range of about 3.3V to 5.5V or less.

Structure

FIG. 4 is a circuit diagram showing an outline structure of a semiconductor device 100 according to the first embodiment of the present invention. As shown in FIG. 4, the semiconductor device 100 has a structure in which a protective circuit 110, an internal circuit 120, and a parasitic diode 130 are connected between a power supply line (i.e., a first power source line) VDD and a grounding line (i.e., a second power source line) GND in parallel.

The protective circuit 110 has a p type MOS transistor (hereinafter referred to as a pMOS) 111 and an n type MOS transistor (hereinafter referred to as an nMOS) 112 connected in series. A drain (i.e., a third terminal) D of the pMOS (i.e., second transistor) 111 and a drain (i.e., a second terminal) D of the nMOS (i.e., first transistor) 112 are connected in common. A source (i.e., a fourth terminal) S of the pMOS 111 is connected to the power supply line VDD, whereas a source (i.e., a first terminal) S of the nMOS 112 is connected to the grounding line GND.

In addition, the pMOS 111 has a gate (i.e., a second control terminal) G connected to the grounding line GND and a back gate B connected to the power supply line VDD. Accordingly, the pMOS 111 will always be turned on (i.e., will always be in a conduction state). On the other hand, the nMOS 112 has both a gate (i.e., a first control terminal) G and a back gate B connected to the grounding line GND. Accordingly, the nMOS 112 will always be turned off (i.e., will always be in a cutoff state). In this description, if the semiconductor device 100 is formed using a p type substrate 1 (q.v. FIG. 5A), for instance, the back gate B of the pMOS 111 will correspond to a portion of a n type well region 26 (q.v. FIG. 5A) of the pMOS 111 formed in the p type substrate 1. Accordingly, the back gate potential of the pMOS 111 will correspond to the well potential of the pMOS 111. Likewise, if the semiconductor device is formed using a p type substrate 1, for instance, the back gate B of the nMOS 112 will correspond to a portion of the p type substrate 1. Accordingly, the back gate potential of the nMOS 112 will correspond to the substrate potential of the p type substrate 1. However, when an n type semiconductor substrate is used, these conditions will be swapped to opposite conductive nature.

Referring to the internal circuit 120, since it is possible to apply a commonly used conventional internal circuit, a detailed explanation thereof will be omitted here. The parasitic diode 130 is a diode that is parasitic in the internal circuit 120.

As described above, the semiconductor device 100 according to this embodiment has a structure in which the protective circuit 110, the internal circuit 120, and the parasitic diode 130 are connected in parallel in between the power supply line VDD and the grounding line GND, while the protective circuit 110 has a structure in which the pMOS 111, which is always turned on, and the nMOS 112, which is always turned off, are connected in series.

Operation

Now, the operation of the semiconductor device 100 according to the first embodiment of the present invention will be described in detail with reference to the drawings. In the following, the operation of the protective circuit 110 will be focused on in particular, and at the same time, an explanation will be given for a situation in which positive surge current is inputted to the power supply line VDD, a situation in which noise is generated at the time of operation, and a situation in which negative surge current is inputted to the power supply line VDD, respectively.

When positive surge current is inputted and when noise is generated at the time of operation

FIG. 5A and FIG. 5B are diagrams for explaining the operation of the protective circuit 110 when positive surge current (also called ESD) flows into the power supply line VDD and when noise is generated at the time of operation. Since the operation of the protective circuit 110 when positive surge current flows into the power supply line VDD and when noise is generated at the time of operation of the semiconductor device 100 are substantially the same, they will be explained together at the same time.

FIG. 5A is a sectional view of the protective circuit 110 showing outline layer structures of the pMOS 111 and the nMOS 112, respectively. FIG. 5B is a schematic figure of the current voltage characteristic (i.e., the I-V characteristic) of the protective circuit 110 when positive surge current flows into the semiconductor device 100. In FIG. 5A, each arrow indicates the current flow when positive surge current is inputted to the VDD line.

Prior to explaining the operation of the protective circuit 110, the outline layer structures of the pMOS 111 and the nMOS 112 will be described first with reference to FIG. 5A.

Outline Layer Structure of pMOS

As shown in FIG. 5A, the pMOS 111, which is one of the component portions making up the protective circuit 110, has a p type substrate 1, a well region 26 formed in the p type substrate 1, a drain 23 and a source 24 formed on the upper part of the well region 26, a gate insulation film 21 and a gate electrode 22 formed on a region of the n type well 26 overlaid between the drain 23 and the source 24, and a back gate 25 formed on the upper part of the well region 26.

The well region 26 and the back gate 25 are diffusion regions which are formed by having n type impurities implanted into certain regions of the p type substrate 1, and they possess n type conductivity. In the back gate 25, however, impurities are diffused such that the back gate 25 will have higher conductivity than the well region 26. In the meantime, the drain 23 and the source 24 are diffusion regions which are formed by having p type impurities implanted into certain regions of the well region 26, and they possess p type conductivity.

In this structure, the back gate 25 is an electrode for controlling the potential (i.e., the well potential) of the well region 26, and it is connected to the power supply line VDD via a predetermined wiring layer. That is, the back gate potential (i.e., the well potential) of the pMOS 111 is supposed to be the power supply potential. Furthermore, the source 24 of the pMOS 111 is connected to the power supply line VDD, and the gate electrode 22 of the pMOS 111 is connected to the grounding line GND. Accordingly, when positive surge current is inputted to the power supply line VDD or at the time of operation (including when noise is generated), the pMOS 111 will be in the same state as when it has relatively negative voltage applied to the gate. In other words, when positive surge current is inputted to the power supply line VDD or at the time of operation (including when noise is generated), the pMOS 111 will always be turned on. Therefore, when positive surge current is inputted to the power supply line VDD or at the time of operation (including when noise is generated), the pMOS 111 will function as a resistance element in which the resistance value is determined by the ON-resistance of the pMOS 111. The drain 23 of the pMOS 111 is connected to a drain 13 of the nMOS 112 via a predetermined wiring layer.

Outline Layer Structure of nMOS

The nMOS 112, which is another component portion making up the protective circuit 110, has a p type substrate 1, a drain 13 and a source 14 formed on the upper part of the p type substrate 1, a gate insulation film 11 and a gate electrode 12 formed on a region of the p type substrate 1 overlaid between the drain 13 and the source 14, and a back gate 15 formed on the upper part of the p type substrate 1.

The back gate 15 is a diffusion region which is formed by implanting p type impurities into a certain region of the p type substrate 1, and it possesses p type conductivity. In the back gate 15, however, impurities are diffused such that the back gate 15 will have higher conductivity than the p type substrate 1. In contrast, the drain 13 and the source 14 are diffusion regions which are formed by implanting n type impurities into certain regions of the p type substrate 1, and they possess n type conductivity.

In this structure, the back gate 15 is an electrode for controlling the potential of the p type substrate 1, and it is connected to the grounding line GND via a predetermined wiring layer. That is, the back gate potential of the nMOS 112 is supposed to be a ground potential. Furthermore, the source 14 and the gate electrode 12 of the nMOS 112 are connected to the grounding line GND. That is, the nMOS 112 according to this embodiment is functioning as a GGNMOS. Therefore, at the time of normal operation, the nMOS 112 will be turned off.

In this regard however, the nMOS 112 will operate while it has a parasitic bipolar transistor pt that is parasitic when positive surge current is inputted or when noise is generated at the time of operation. The parasitic bipolar transistor pt has a structure in which the collector thereof is connected to the drain 13, the emitter thereof is connected to the source 14 and the base thereof is connected to the back gate 15 via a substrate resistance R1 of the p type substrate 1. When surge current is inputted to the power supply line VDD or noise is generated at the time of operation, the parasitic bipolar transistor pt will turn on by the surge current or noise, and the surge current or generated noise current will be discharged to the grounding line GND through the parasitic bipolar transistor pt.

In the following, the operation of the protective circuit 110, that is the operation at the time when the surge current is dissipated to the grounding line GND as the parasitic bipolar transistor pt is parasitic in the nMOS 112 is turned on, will be described with reference to FIG. 5A and FIG. 5B. In the following, an explanation will be first given of the operation of the pMOS 111 and second given of the operation of the nMOS 112, the pMOS 111 and the nMOS 112 being connected in series between the power line VDD and the grounding line GND. Then, based on this explanation, the operation of the protective circuit 110 made up of the pMOS 111 and the nMOS 112 will be explained.

Operation of pMOS 111

As described above, when positive surge current is inputted to the power supply line VDD or at the time of operation (including when noise is generated), the pMOS 111 will function as a resistance element in which the resistance value is determined by the ON-resistance of the pMOS 111. Accordingly, as shown in FIG. 5B, the characteristic curve F1 of the pMOS 111 in such cases will be an approximate straight line with a slope like the one that line F1′ has. That is, a current Ip′ (q.v. FIG. 5A) will flow to the pMOS 111 in accordance with the ON-resistance of the pMOS 111 and the potential difference V generated between the source and drain.

Operation of nMOS 112

In contrast, as mentioned above, in when positive surge current is inputted or when noise is generated at the time of operation, the nMOS 112 will operate with the parasitic bipolar transistor pt. At this time, the characteristic of the nMOS 112 will be as shown by the characteristic curve D1 in FIG. 5B.

As shown by the characteristic curve D1 of FIG. 5B, when positive surge current is inputted to the power supply line VDD or when noise is generated at the time of operation, first, a drain voltage V_{D} applied between the n type drain 13 and the p type substrate 1 will rise. After that, at a time a′ when the drain voltage V_{D} of the nMOS 112 surpasses the breakdown voltage of the PN junction formed by the drain 13 and the p type substrate 1, the current Ia′ (q.v. FIG. 5A) will flow from the drain 13 to the p type substrate 1.

Next, as shown in FIG. 5B, along with the rise of the drain voltage V_{D} (i.e., a shift from the time a′ to time b′), the current Ia′ flowing from the drain 13 to the p type substrate 1 will increase, by which the potential of the p type substrate 1 will rise. In this regard, however, a portion of the current Ia′ that has flowed into the p type substrate 1 will be discharged to the grounding line GND via the substrate resistance R1 and the back gate 15, as a base current Ib′.

After that, at a time c′ when the potential of the p type substrate 1 rises to a value higher than the source potential of the source 14 by the amount of the forward voltage Vf of the PN junction, the parasitic bipolar transistor pt that is parasitic in the nMOS 112 will turn on, and a forward current Ic′ (q.v. FIG. 5A) will flow between the p type substrate 1 and the source 14. Here, the forward voltage Vf of the PN junction, for instance, may be about 0.6V if the p type substrate 1 is a silicon substrate.

When the parasitic bipolar transistor pt is turned on as described above, a collector current Id′ (q.v. FIG. 5A) will flow through the drain 13 (i.e., the collector of the parasitic bipolar transistor pt) and the source 14 (i.e., the emitter of the parasitic bipolar transistor pt), and thereby, the drain voltage V_{D} will drop rapidly (i.e., shift from the time c′ to time d′) as shown in FIG. 5B. After that (i.e., after the time d′), the nMOS 112 will function as a resistance element with a resistance value being the ON-resistance of its parasitic bipolar transistor pt. Therefore, in the characteristics of the nMOS 112, the drain current Id′ will rise approximately linearly along with the rise of the drain voltage V_{D}. By this operation, the positive current inputted to the power supply line VDD or the surge current caused by the noise generated at the time of operation will be discharged to the grounding line GND.

In this way, when positive surge current is inputted or when noise is generated at the time of operation, the nMOS 112 will operate to turn on the parasitic bipolar transistor pt and let the surge current be absorbed by the grounding line GND as the base current Ib′ and as the collector current Id′.

Operation of Protective Circuit 110

Based on the above-described operations of the pMOS 111 and nMOS 112, the operation of the protective circuit 110 according to this embodiment will be as described below.

The pMOS 111 will function as a resistance element, which limits the current flowing into the protective circuit 110, mainly after the parasitic bipolar transistor pt of the nMOS 112 is turned on (q.v. a time c in FIG. 5B) and the electric charge accumulated at the drain 13 is discharged (i.e., after a time d in FIG. 5B). A characteristic curve corresponding to the time period from the point the parasitic bipolar transistor pt is turned on to the point the electric charge accumulated at the drain 13 is discharged (i.e., from the time a to time d in FIG. 5B) is approximately the same as with the nMOS 112 as a single body, and therefore, a detailed explanation thereof will be omitted here.

Accordingly, beyond the time d, the characteristic curve G1 of the protective circuit 110 can be obtained by adding a voltage component (horizontal axis) in the characteristic curve F1 of the pMOS 111 to a voltage component (horizontal axis) in the characteristic curve D1 of the nMOS 112

Here, in order to supplement the explanation, a supplemental line Z-Z which passes through the time point d′ and runs parallel to the vertical axis will be drawn, and a line F1″ which runs parallel to the line F1′ showing the slope of the characteristic curve F1 of the pMOS 111 will be drawn from an intersection of the supplement line Z-Z and the horizontal axis. Then, as shown by distances X1 and X2 in FIG. 5B, when the drain current I_{D} is the same, the distance between an arbitrary point on the supplemental line Z-Z (provided that the point is beyond the time d′) and the characteristic curve D1 of the nMOS 112, and the distance between an arbitrary point on the line F1″ and the characteristic curve G1 of the protective circuit 110, will become the same.

In this way, the protective circuit 110 according to this embodiment has a structure in which the pMOS 111 and the nMOS 112 are connected in between the power supply line VDD and the grounding line GND in series, the pMOS 111 functioning as a resistance element by always being turned on when positive surge current is inputted to the power supply line VDD or at the time of operation (including when noise is generated), and the nMOS 112 operating as having the parasitic bipolar transistor pt being parasitic when positive surge current is inputted to the power supply line VDD or at the time of operation (including when noise is generated). In other words, the protective circuit 110 will operate in the same way as a circuit having a resistance element, in which the resistance value thereof is determined by the ON-resistance of the pMOS 111, connected in between the power supply line VDD and the drain of the nMOS 112.

Here, the ON-resistance of the pMOS 111 can be set to an arbitrary value by controlling the gate length and the gate width of the pMOS 111. That is, in the protective circuit 111 according to this embodiment, it is possible to set the ON-resistance of the pMOS 111 to a desired value by controlling the gate length and the gate width of the pMOS 111. Therefore, according to this embodiment, it is possible to realize a protective circuit 110 which is capable of easily drawing in positive surge current inputted to the power supply line VDD and also capable of preventing possible breakdown that can be caused by noise at the time of actual operation, and a semiconductor device 100 including such protective circuit 110.

When Negative Surge Current is Inputted

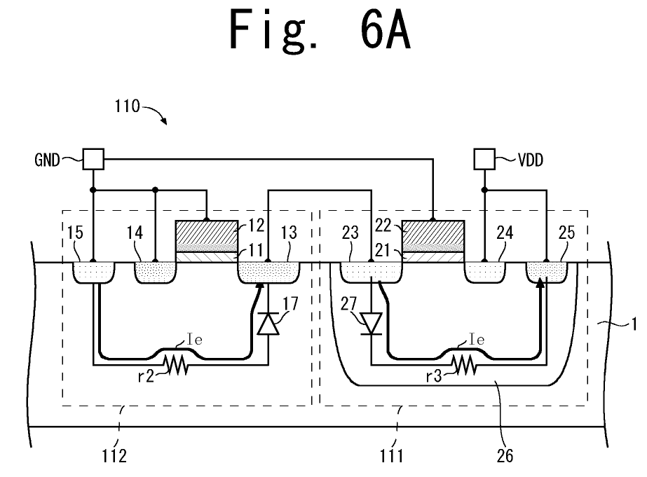

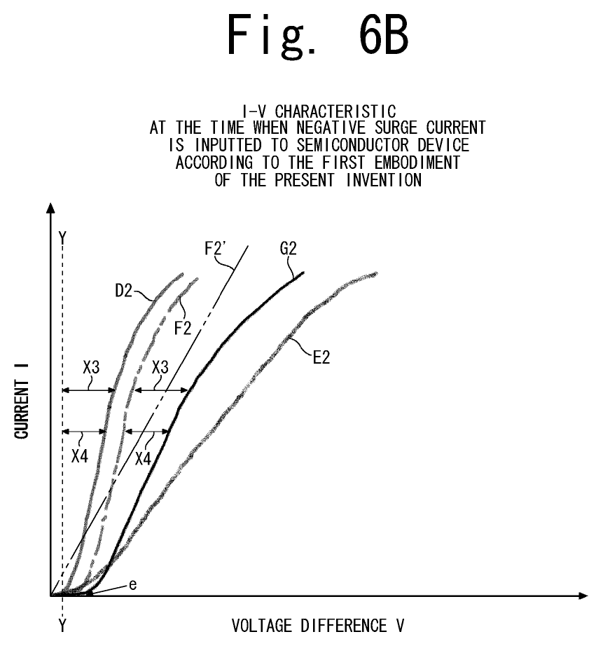

Now the operation of the protective circuit 110 when negative surge current is inputted to the power supply line VDD will be explained. FIG. 6A and FIG. 6B are diagrams for explaining the operation of the protective circuit 110 when negative surge current is inputted to the power supply line VDD. FIG. 6A is a sectional view of the protective circuit 110 showing outline layer structures of the pMOS 111 and the nMOS 112, respectively. FIG. 6B is a schematic figure of the current voltage characteristic (i.e., the I-V characteristic) of the protective circuit 110 when negative surge current flows into the semiconductor device 100. In FIG. 6A, each arrow indicates the current flow at the time when negative surge current is inputted to the VDD line.

Since the outline layer structures of the pMOS 111 and the nMOS 112 are the same as those explained with reference to FIG. 5A, a detailed explanation thereof will be omitted here.

As shown in FIG. 6A, when negative surge current is inputted to the power supply line VDD, the pMOS 111 will operate as having a PN junction diode 27, in which the anode thereof is the p type drain 23 and the cathode thereof is the n type well region 26, that is parasitic in a forward direction with respect to the current flow. Likewise, the nMOS 112 will operate as having a PN junction diode 17, in which the anode thereof is the p type substrate 1 and the cathode thereof is the n type drain 13, that is parasitic in a forward direction with respect to the current flow (q.v. FIG. 6A). Accordingly, as shown in FIG. 6B, the characteristic curves F2 and D2 of the pMOS 111 and the nMOS 112, respectively, will become the characteristic curves of the forward PN junction diodes.

From these facts, when negative surge current is inputted to the power supply line VDD, the protective circuit 110 according to this embodiment will be equivalent to a circuit structure in which forward PN junction diodes, as the above-mentioned forward PN junction diodes 17 and 27, are connected in series in between the grounding line GND and the power supply line VDD. Accordingly, as shown in FIG. 6B, the characteristic curve G2 of the protective circuit 110 can be obtained by adding a voltage component (horizontal axis) in the characteristic curve F2 of the pMOS 111 to a voltage component (horizontal axis) in the characteristic curve D2 of the nMOS 112. Then as shown by distances X3 and X4 in FIG. 6B, when the drain current I_{D} is the same, the distance between an arbitrary point on a supplemental line Y-Y and the characteristic curve D2 of the nMOS 112 and the distance between an arbitrary point on the characteristic curve F2 and the characteristic curve G2 of the protective circuit 110 will become the same.

As a result, when negative surge current is inputted to the power supply line VDD, in the protective circuit 110 according to this embodiment, the potential difference V applied between each anode (i.e., the drain 23 or the p type substrate 1) and cathode (i.e., the well region 26 or the drain 13) will immediately reach a forward voltage Vf of the PN junction, and thereby, the negative surge current will be immediately dissipated to the grounding line GND via the pMOS 111 and the nMOS 112. In this respect, when the p type substrate 1 is a silicon substrate, for instance, the forward voltage Vf of the PN junction should be about 0.6V.

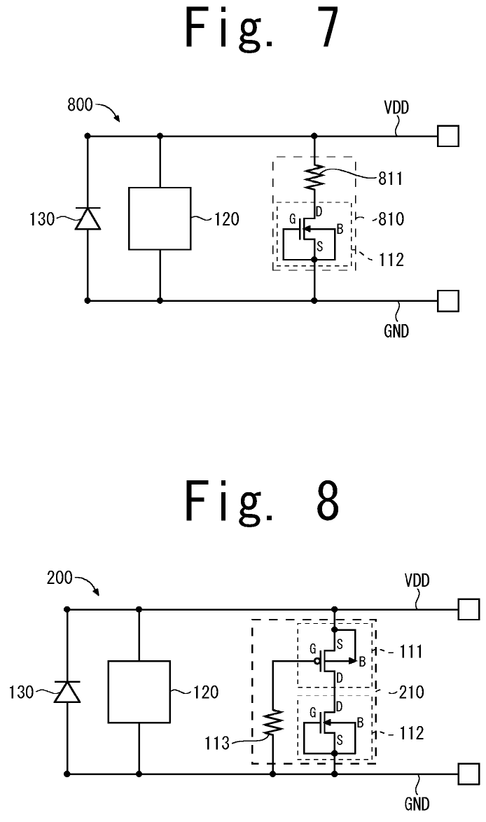

Now, in order to show the effects that can be achieved by this embodiment more clearly, a comparative example 1 as shown in FIG. 7 will be referred to. As shown in FIG. 7, a semiconductor device 800 of the comparative example 1 has a structure in which a protective circuit 810, an internal circuit 120, and a parasitic diode 130 are connected in parallel in between a power supply line VDD and a grounding line GND.

The protective circuit 810 has an nMOS 112 connected in between the power supply line VDD and the grounding line GND, and a resistor 811 connected in between a drain D of the nMOS 112 and the power supply line VDD. As with the nMOS 112 in the first embodiment, the nMOS 112 in the comparative example 1 has a gate G, a source S and a back gate B connected to the grounding line GND, respectively. Accordingly, when the semiconductor device 800 is at normal operation, the nMOS 112 will always be turned off.

Since the internal circuit 120 and the parasitic diode 130 are the same as those in the first embodiment (q.v. FIG. 4), a detailed description thereof will be omitted here.

As described above, the semiconductor device 800 in the comparative example 1 has a structure in which the protective circuit 810, the internal circuit 120, and the parasitic diode 130 are connected in parallel in between a power supply line VDD and a grounding line GND, while the protective circuit 810 has a structure in which the resistance 811 and the nMOS 112, which is always turned off at the time of normal operation, are connected in series. In other words, the semiconductor device 800 has a circuit structure equivalent to the protective circuit 110 as shown in FIG. 4, except that the pMOS 111 of the protective circuit 110 is replaced by the resistor 811 in the semiconductor device 800.

Thus, the semiconductor device 800 has a circuit structure equivalent to the protective circuit 110 as shown in FIG. 4 except that the pMOS 111 of the protective circuit 110 is replaced by the resistance 811 in the semiconductor device 800. Therefore, provided that the resistance value of the resistance 811 is the same as the ON-resistance value of the pMOS 111, the operation of the protective circuit 810 when positive surge current is inputted to the power supply line VDD or when noise is generated at the time of operation will become approximately the same as the operation of the protective circuit 110. Accordingly, the characteristic of the resistor 811 will be represented by a line having the same slope as that of the line F1′ shown in FIG. 5B. Therefore, under such conditions, the characteristic curve of the protective circuit 810 can be obtained by adding a voltage component (horizontal axis) to the characteristic of the resistor 811 (i.e., the line F1′) to a voltage component (horizontal axis) in the characteristic curve D1 of the nMOS 112, as shown in FIG. 5B. Thus, the characteristic curve of the protective circuit 810 will become substantially the same as the characteristic curve G1 of the protective circuit 110 in the first embodiment.

On the other hand, the operation of the protective circuit 810 when negative surge current is inputted to the power supply line VDD will be an operation in which the PN junction diode 27 that is parasitic in the pMOS 111 of the protective circuit 110 is replaced with the resistor 811. As described above, the characteristic of the resistor 811 will become as represented by a line F2′ (q.v. FIG. 6B) which is parallel to the line F1′ (q.v., FIG. 5B). Accordingly, as shown in FIG. 6B, the characteristic curve E2 of the protective circuit 810 when negative surge current is inputted to the power supply line VDD can be obtained by adding a voltage component (horizontal axis) in the characteristic of the resistor 811 (i.e., the line F2′) to a voltage component (horizontal axis) in the characteristic curve D2 of the nMOS 112.

Now, as can be seen from the characteristic curve G2 of the protective circuit 110 and the characteristic curve E2 of the protective circuit 810 shown in FIG. 6B, for the most part, the current I flowing with respect to the same voltage difference V is always greater with respect to the protective circuit 110 as compared to the protective circuit 810. In other words, in the first embodiment of the present invention, the ability of the protective circuit 110 to smoothly allow surge current flow is improved. Here, the resistance value of the resistance 811 is the same as the ON-resistance value of the pMOS 111.

Thus, compared to the protective circuit 810 in the comparative example 1, the protective circuit 110 in the first embodiment of the present invention has an improved ability to allow negative surge current to smoothly flow without losing its ability to allow positive surge current or surge current caused by noise at the time of operation to smoothly flow. Because the protective circuit 810 in the comparative example 1 has the resistor 811 connected to the PN junction diode 17 in series for the purpose of current restriction, it has to sacrifice its protective function with respect to negative surge current which is not originally necessary to be restricted. On the other hand, with respect to the protective circuit 110 in the first embodiment of the present invention, because it has the nMOS 112 and the pMOS 111 operating as the forward PN junction diodes 17 and 27, respectively, it is capable of maintaining good protective function.

Moreover, compared to the case where the protective circuit is made up of a GGNMOS alone, the protective circuit 110 in the first embodiment of the present invention has the pMOS 111, which functions as a load resistance when noise is generated at the time of operation, disposed in between the nMOS 112 and the power supply line VDD, and thus it is capable of preventing a considerably large surge current from flowing into the nMOS 112 at the time when noise is generated. As a result, the present invention is capable of preventing permanent breakdown, which could be caused by noise-caused surge current from occurring inside the chip.

In addition, the protective circuit 110 in this embodiment can work more effectively than the protective circuit 810 in the comparative example 1 under certain preconditions. That is, by setting the protection resistance efficiency such that the pMOS 112 has a smaller value than that of the resistor 811 in the comparative example 1, the protective circuit 110 can have an improved ability to allow positive surge current or surge current caused by noise at the time of operation to smoothly flow. In other words, by making the slope of the characteristic by the ON-resistance of the pMOS 111 steeper than the slope of the characteristic of the resistance 811, and by setting the ON-resistance value (gentle slope) of the p-MOS 111 to the extent that no breakdown will be caused even when the parasitic bipolar transistor pt is turned on at the time of actual operation, it will become possible to prevent possible breakdown that can be caused by noise at the time of actual operation, while also maintaining the ability to smoothly draw surge current in. Such arrangements can be made without having to change any of the manufacturing processes, since the ON-resistance of the pMOS 111 is adjustable by adjusting the gate length and the gate width.

As described above, the semiconductor device 100 with the protective circuit 110 according to the first embodiment of the present invention has the power supply line VDD, the grounding line GND, the nMOS 112 electrically connected to the grounding line GND, and the pMOS 111 connected in between the power supply line VDD and the nMOS 112, the pMOS 111 functioning to electrically connect the power supply line VDD and the nMOS 112 when an operation bias voltage is being applied between the power supply line VDD and the grounding line GND, i.e., when an operation voltage is being applied to the power supply line VDD.

In this structure, the pMOS 111, which electrically connects the power supply line VDD and the nMOS 112 when operation bias voltage is being applied between the power supply line VDD and the grounding line GND, i.e., when the semiconductor device 100 is in an active state (i.e., at the time of operation), will function as a resistance element for restricting the current flowing between the power supply line VDD and the grounding line GND via the nMOS 112 and the pMOS 111 at the time when the semiconductor device 100 is operating. Accordingly, surge current that can be caused by noise generated at the time when the semiconductor device 100 is operating can be restricted by the pMOS 111 functioning as a resistance element. At this time, the resistance value of the pMOS 111 is determined by the ON-resistance of the pMOS 111. Therefore, by controlling this ON-resistance, it will become possible to prevent excessive amount of current generated by noise caused at the time of operation from flowing into the nMOS 112 and the pMOS 111, and therefore prevent consequential permanent breakdown to be caused. This means that by applying the pMOS 111, which functions as a resistance element at the time when the semiconductor device 100 is operating, the semiconductor device 100 will be able to achieve improved immunity against noise.

Furthermore, when positive surge current is inputted to the power supply line VDD, the pMOS 111 will be in a conducting state. Therefore, by controlling the ON-resistance of the pMOS 111 so as to achieve the ability to smoothly draw positive surge current in while considering the immunity against noise, it will become possible to maintain the ability to smoothly draw surge current in, while also preventing excessive amount of current from flowing into the nMOS 112 and the pMOS 111 at the time when noise is generated. This means that the semiconductor device 100 is capable of achieving appropriate robustness against both noise and surge current.

Moreover, if, for instance, negative surge current is inputted to the power supply line VDD, both the nMOS 112 and the pMOS 111 will function as the PN junction diodes 17 and 27, which are connected in a forward direction with respect to the current flow. Therefore, as compared to a structure in which only a resistance element is disposed in between the nMOS 112 and the power supply line VDD, for instance (e.g. comparative example 1), the present invention is capable of achieving an improved ability to smoothly draw negative surge current in. This means that the semiconductor device 100 is capable of achieving improved robustness against negative surge current.

In order to achieve the effects as described above, the nMOS 112 according to this embodiment can also be structured, for instance, to include a source S connected with the grounding line GND, a drain D, and a gate G connected with the grounding line GND. In the meantime, the pMOS 111 which contributes to achieving the effects as described above is structured, for instance, to include a drain D connected with the drain D of the nMOS 112, a source S connected with the power supply line VDD, and a gate G connected with the grounding line GND.

Second Embodiment

Next, a second embodiment of the present invention will be described in detail with reference to the drawings. In the following, the same reference numbers will be used for the structural elements that are the same as the first embodiment, and redundant explanations of those structural elements will be omitted.

In this embodiment, as in the first embodiment, a semiconductor device which is manufactured through a high withstand voltage process and which operates by means of a comparatively high operation voltage in a range of about several to several dozen volts will be described as an example. However, the present invention is not limited by such factors, and it may be a semiconductor device which operates by means of a normal operation voltage in a range of about 3.3V to 5.5V or less.

FIG. 8 is a circuit diagram showing an outline structure of a semiconductor device 200 according to the second embodiment of the present invention. As shown in FIG. 8, the semiconductor device 200 has the same structure as the semiconductor device 100 in the first embodiment (q.v., FIG. 4) except that it further has a resistor (a resistance element) 113 between the gate G of the pMOS 111 and the grounding line GND. That is, a protective circuit 210 in this embodiment has the pMOS 111 and the nMOS 112 connected in series between the power supply line VDD and the grounding line GND, and the resistor 113 connected with the gate G of the pMOS 111.

In this way, the protective circuit 210 according to this embodiment has a structure in which the resistor 113 for preventing excessive amount of current from being applied to the gate G of the pMOS 111 is connected to the gate G of the pMOS 111. With this structure, the rise in electrical potential of the gate G of the pMOS 111 will be delayed based on the time constant formed by the resistor 113 and the parasitic capacitance around the resistor 113, and thereby it is possible to prevent an instantaneous and considerably large potential from being applied to the gate G of the pMOS 111 at the time when positive surge current is inputted to the power supply line VDD. Therefore, it is possible to reliably prevent the thin gate insulation film 21, existing between the gate electrode 22 and the source 24 that make up the pMOS 111, from being damaged by an excessive amount of current generated between the gate G of the pMOS 111 and the grounding line GND.

The rest of the structure and operation thereof are the same as in the first embodiment of the present invention, and therefore, redundant explanations thereof will be omitted.

As described above, the semiconductor device 200 with the protective circuit 210 according to the second embodiment of the present invention is structured to further include the resistor 113 connected between the gate G of the pMOS 111 and the grounding line GND in addition to the structure of the semiconductor device 100 in the first embodiment.

By having such structure, the semiconductor device 200 in the second embodiment of the present invention is capable of achieving the effects as achieved by the first embodiment of the present invention, and more than that, the semiconductor device 200 is capable of reliably preventing the thin gate insulation film 21, existing between the gate electrode 22 and the source 24 that make up the pMOS 111, from being damaged by an excessive amount of current generated between the gate G of the pMOS 111 and the grounding line GND.

Third Embodiment

Next, a third embodiment of the present invention will be described in detail with reference to the drawings. In the following, the same reference numbers will be used for the structural elements that are the same as the first or second embodiment, and redundant explanations of those structural elements will be omitted.

In this embodiment, as in the first and second embodiments, a semiconductor device which is manufactured through a high withstand voltage process and which operates by means of a comparatively high operation voltage in a range of about several to several dozen volts will be described as an example. However, the present invention is not limited by such factors, and it may be a semiconductor device which operates by means of a normal operation voltage in a range of about 3.3V to 5.5V or less.

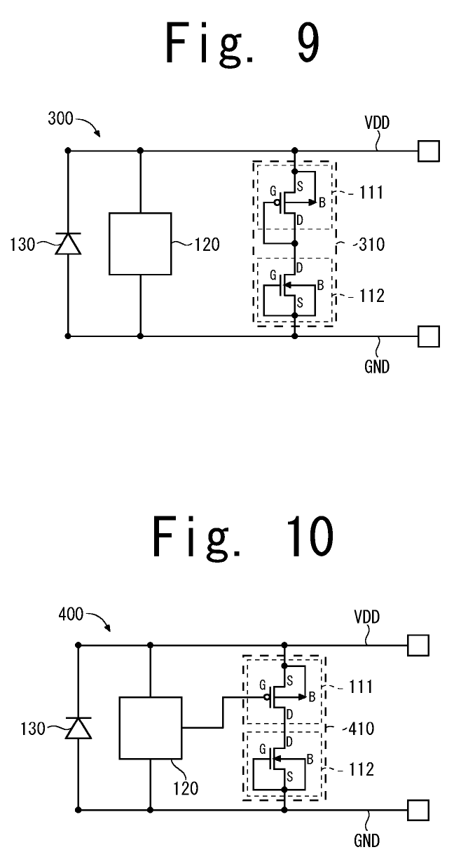

FIG. 9 is a circuit diagram showing an outline structure of a semiconductor device 300 according to the third embodiment of the present invention. As shown in FIG. 9, the semiconductor device 300 has the same structure as the semiconductor device 100 in the first embodiment (q.v., FIG. 4) except that the gate G of the pMOS 111 is connected to the drain D of the pMOS 111 and the drain D of the nMOS 112. That is, in a protective circuit 310 of this embodiment, the drain voltage of the nMOS 112 is applied to the gate G of the pMOS 111.

In this way, the protective circuit 310 according to this embodiment has a structure in which the gate G of the pMOS 111 is connected to the drain D of the pMOS 111 and the drain D of the nMOS 112. In the other words, the gate G of the pMOS 111 is connected to the grounding line GND via the nMOS 112. With this structure, at the time when positive surge current is inputted to the power supply line VDD, the gate potential of the pMOS 111 will become higher than the electrical potential of the grounding line GND by as much as the ON-resistance of the nMOS 112. However, the pMOS 111 will function as a protective resistance by using a resistance component in the unsaturation region in the pMOS 111, and this function will not be greatly influenced by the rise in the gate potential. That is, the rise in the gate potential in the pMOS 111 will not have a great influence on the operation of the pMOS 111. Likewise, the function of the pMOS 111 as a limiting resistor will not be greatly influenced by the rise in the gate potential.

When positive surge current is inputted to the power supply line VDD or when noise occurs at the time of operation, an excessive amount of voltage will be impressed to the thin gate insulation film 21 between the gate electrode 22 (the gate G) and the source 24 (the source S) of the pMOS 111 after a parasitic bipolar transistor of the nMOS 112 has turned on and the surge current flows through both the pMOS 111 and the nMOS 112. Before the surge current begins to flow through both the pMOS 111 and the nMOS 112, the source 24 (the source S) and the gate electrode 22 (the gate G) are capacitive-coupled by the well region 26 in a state where the gate electrode 22 and the source 24 form a p-n junction. Therefore, at this point, the source potential and the gate potential in the pMOS 111 are substantively the same. Moreover, after the surge current begins to flow through both the pMOS 111 and the nMOS 112, the ON-resistance of the nMOS 112 will not exist between the drain D and the gate G of the pMOS 111, and thus, there will be little potential difference between the source S and the drain D of the pMOS 111. Therefore, it will be possible to more reliably prevent the thin gate insulation film 21 between the gate electrode 22 (the gate G) and the source 24 (the source S) of the pMOS 111 from being damaged.

Since the forward characteristic of the PN junction diode 27 against negative surge current is not influenced by the gate potential of the pMOS 111, it is the same as the first or second5 embodiment.

The rest of the structure and operation thereof are the same as in the first embodiment of the present invention, and therefore, redundant explanations thereof will be omitted.

As described above, the semiconductor device 300 with the protective circuit 310 according to the third embodiment of the present invention has the same structure of the semiconductor device 100 in the first embodiment, except for the portion in which that the gate G of the pMOS 111 is connected to the drain D of the pMOS 111.

By having such structure, the semiconductor device 300 in the third embodiment of the present invention is capable of achieving the effects achieved by the first embodiment of the present invention, and moreover, the semiconductor device 300 is capable of preventing, with more precision, the thin gate insulation film 21 existing between the gate electrode 22 (gate G) and the source 24 (source S) from receiving excessive amount of voltage due to the excessive amount of voltage generated between the grounding line GND and the gate G of the pMOS 111 at the time when positive surge current is applied to the power supply line VDD.

Fourth Embodiment

Next, a fourth embodiment of the present invention will be described in detail with reference to the drawings. In the following, the same reference numbers will be used for the structural elements that are the same as the first, second or third embodiment, and redundant explanation of those structural elements will be omitted.

In this embodiment, as in the first to third embodiments, a semiconductor device which is manufactured through a high withstand voltage process and which operates by a comparatively high operation voltage in a range of about several to several dozen volts will be described as an example. However, the present invention is not limited by such factors, and it may be a semiconductor device which operates by a normal operation voltage in a range of about 3.3V to 5.5V or less.

FIG. 10 is a circuit diagram showing an outline structure of a semiconductor device 400 according to the fourth embodiment of the present invention. As shown in FIG. 10, the semiconductor device 400 has the same structure as the semiconductor device 100 (q.v., FIG. 4) except that the gate G of the pMOS 111 is connected to the internal circuit 120. That is, in a protective circuit 410 in this embodiment, the pMOS 111 is controlled to turn ON/OFF by means of a control voltage output from the internal circuit 120.

When the internal circuit 120 is active, it will generate a control voltage for turning the pMOS 111 OFF and input the control voltage to the gate G of the pMOS 111. Thus, the protective circuit 410 has a structure in which the pMOS 111 is turned OFF at the time of operation by having the control voltage from the internal circuit 120 supplied to the gate G of the pMOS 111. In the semiconductor device 400 of this embodiment, the gate G of the pMOS 111 will be connected to the grounding line GND via the internal circuit 120 when not being operated.

Here, the problem of breakdown that can be caused by surge current will occur at the time when the operating voltage is not applied between the power supply line VDD and the grounding line GND, i.e., at the time when the semiconductor device 400 is inactive (this problem can occur in the same way with respect to the semiconductor devices 100 to 300 in the first to third embodiments). When the semiconductor device 400 (or the semiconductor devices 100 to 300 in the first to third embodiments) is inactive, the electrical potential of the gate G of the pMOS 111 is indeterminate. Therefore, if positive surge current is inputted into the power supply line VDD, a voltage of Low level will be inputted into the gate G of the pMOS 111. Thereby, in this situation, the pMOS 111 will be turned ON. Operation in this situation is the same as the protective function against positive surge current as described in the first embodiment, and therefore, redundant explanations thereof will be omitted.

On the other hand, the problem of breakdown that can be caused by noise will occur at the time when the semiconductor device 400 is active (this problem can occur in the same way with respect to the semiconductor devices 100 to 300 in the first to third embodiments). When the semiconductor device 400 is active, a voltage of High level will be inputted into the gate G of the pMOS 111 from the internal circuit 120. Thereby, in this situation, the pMOS 111 will be turned OFF. With this structure, it is possible to set a resistance for limiting current to an infinite value.

As in the first and second embodiments, since the forward characteristic of the PN junction diode 27 against negative surge current is originally not influenced by the gate potential of the pMOS 111, it is the same as the first or second embodiment.

The rest of the structure and operation thereof are the same as in the first embodiment of the present invention, and therefore, redundant explanations thereof will be omitted.

As described above, the semiconductor device 400 with the protective circuit 410 according to the fourth embodiment of the present invention has the power supply line VDD, the grounding line GND, the nMOS 112 electrically connected with the grounding line GND, the internal circuit 120 connected in between the power supply line VDD and the grounding line GND, and the pMOS 111 connected in between the power supply line VDD and the nMOS 112, the pMOS 111 functioning to shut off the electrical connection between the power supply line VDD and the nMOS 112 when control voltage is being supplied to the gate G from the internal circuit 120.

With this structure, when an operation bias voltage is applied between the power supply line VDD and the grounding line GND, i.e., when the semiconductor device 400 is in an active state (i.e., at the time of operation), it is possible to prevent possible surge current caused by noise generated when the semiconductor device 400 is operating from flowing into the nMOS 112 and the pMOS 111, by shutting off the electrical connection between the power supply line VDD and the nMOS 112 using the pMOS 111. This means that by applying the pMOS 111, which functions to prevent possible surge current caused by noise generated at the time when the semiconductor device 400 is operating from flowing into itself and to the nMOS 112, the semiconductor device 400 will be able to have improved immunity against noise.

Moreover, by arranging the gate G of the pMOS 111 to connect with the grounding line GND via the internal circuit 120, for instance, it will be possible to have the pMOS 111 become conductive when positive surge current is inputted to the power supply line VDD, for instance. Accordingly, by controlling the ON-resistance of the pMOS 111 so as to achieve the ability to smoothly draw positive surge current in, it will become possible to maintain the ability to smoothly draw surge current in.

In addition, if, for instance, negative surge current is inputted to the power supply line VDD, both the nMOS 112 and the pMOS 111 will function as the PN junction diodes 17 and 27 which are connected in a forward direction with respect to the current flow. Therefore, as compared to a structure in which only a resistance element is disposed in between the nMOS 112 and the power supply line VDD, for instance (e.g. comparative example 1), the present invention is capable of achieving improved ability to smoothly draw negative surge current in. This means that the semiconductor device 400 is capable of achieving improved robustness against negative surge current.

Therefore, according to the fourth embodiment of the present invention, the semiconductor device 400 is capable of achieving appropriate robustness against both noise and surge current.

While the preferred embodiments of the invention have been described using specific terms, such description is for illustrative purposes only, and it is to be understood that changes and variations may be made without departing from the spirit or the scope of the following claims.

This application claims priority to Japanese Patent Application No. 2005-265096. The entire disclosures of Japanese Patent Application No. 2005-265096 is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

The term “configured” as used herein to describe a component, section or part of a device includes hardware and/or software that is constructed and/or programmed to carry out the desired function.

Moreover, terms that are expressed as “means-plus function” in the claims should include any structure that can be utilized to carry out the function of that part of the present invention.

The terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

What is claimed is:

1. A semiconductor device comprising:
first and second lines;
a first transistor configured to electrically connect with the second line; and
a second transistor configured to electrically connect with the first line and the first transistor, the second transistor being turned ON when a bias voltage for operation is impressed between the first and second lines.

2. The semiconductor device according to claim 1, wherein
the first transistor comprises
a first terminal configured to electrically connect with the second line,
a second terminal, and
a first control terminal configured to electrically connect with the second line, and
the second transistor comprises
a third terminal configured to electrically connect with the second terminal,
a fourth terminal configured to electrically connect with the first line,
and a second control terminal configured to electrically connect with the second line.

3. The semiconductor device according to claim 2, wherein
the second transistor further comprises a resistance element configured to electrically connect with the second control terminal and the second line.

4. The semiconductor device according to claim 1, wherein
the first transistor comprises
a first terminal configured to electrically connect with the second line,
a second terminal, and
a first control terminal configured to electrically connect with the second line, and
the second transistor comprises
a third terminal configured to electrically connect with the second terminal,
a fourth terminal configured to electrically connect with the first line, and
a second control terminal configured to electrically connect with the second terminal.

5. The semiconductor device according to claim 1, wherein
the first line is a power supply line,
the second line is a grounding line,
the first transistor is an n type transistor, and
the second transistor is a p type transistor.

6. A semiconductor device comprising:
first and second lines;
a first transistor configured to electrically connect with the second line;
an internal circuit configured to electrically connect with the first and second lines;
a second transistor configured to electrically connect with the first line and the first transistor, the second transistor turning OFF when a control voltage is inputted into the second terminal thereof from the internal circuit.

7. The semiconductor device according to claim 6, wherein
the first transistor comprises
a first terminal configured to electrically connect with the second line,
a second terminal, and
a first control terminal configured to electrically connect with the second line, and
the second transistor comprises
a third terminal configured to electrically connect with the second terminal,
a fourth terminal configured to electrically connect with the first line, and
a second control terminal configured to electrically connect with the internal circuit.

8. The semiconductor device according to claim 6, wherein
the first line is a power supply line,
the second line is a grounding line,
the first transistor is an n type transistor, and
the second transistor is a p type transistor.

9. A semiconductor device, comprising:
a first node to which a power supply voltage is impressed;
a second node to which a ground voltage is impressed;
a first transistor electrically connected with the second node, the first transistor having a control electrode electrically connecting to the second node; and
a second transistor electrically connected between the first node and the first transistor, the second transistor having a control electrode electrically connecting to the second node.
